(19) United States
(12) Patent Application Publication
(10) Pub. No.: US 2009/0095508 A1
(43) Pub. Date: Apr. 16, 2009

(54) Printed circuit board and method for manufacturing the same

(75) Inventors: Jung-Hyun Park, Dong-gu (KR); Ji-Eun Kim, Gwangmyeong-si (KR); Myung-Sam Kang, Seo-gu (KR)

Correspondence Address: STAAS & HALSEY LLP, SUITE 700, 1201 NEW YORK AVENUE, N.W., WASHINGTON, DC, 20005, US

(73) Assignee: Samsung Electro-Mechanics Co., Ltd., Suwon (KR)

(21) Appl. No.: 12/149,610

(22) Filed: May 5, 2008

(30) Foreign Application Priority Data
Oct. 16, 2007 (KR) 10-2007-0103894

(51) Int. Cl. H05K 1/00; H05K 3/02

(52) U.S. Cl. 174/250; 29/846

(57) ABSTRACT

A printed circuit board and a method for manufacturing the same are disclosed. The manufacturing method includes: forming a first plating resist corresponding to the circuit pattern on a surface of each of a first carrier and a second carrier; forming a second plating resist corresponding to the pad on each of the surfaces; forming the pad by performing plating over each of the surfaces; stripping the second plating resists; forming the circuit pattern by performing plating over each of the surfaces; pressing the first carrier and the second carrier with an insulation layer interposed between the first carrier and the second carrier such that the circuit patterns face each other; and removing the first carrier and the second carrier. Since plating bars need not be used, the degree of freedom in designing circuits can be increased, and circuits of higher densities can be designed.

### CROSS-REFERENCE TO RELATED APPLICATIONS

This application claims the benefit of Korean Patent Application No. 10-2007-0103894 filed with the Korean Intellectual Property Office on Oct. 16, 2007, the disclosure of which is incorporated herein by reference in its entirety.

### BACKGROUND

1. Technical Field

The present invention relates to a printed circuit board and a method for manufacturing the printed circuit board.

2. Description of the Related Art

In spite of the recent trends towards lighter, thinner, and smaller integrated circuit chips, the number of leads in an IC package is increasing. To counter this, it has become common to use package boards such as of BGA (ball grid array) and CSP (chip scale package) types.

As it is easy to increase the density of the board by using solder balls, many boards are used as package boards on which semiconductor chips can be mounted. A gold plating process may be performed to improve the electrical connection of the wires that connect with the semiconductor chip and the pads that connect with the solder balls.

Here, the gold plating process may be performed using gold-plating bars. These plating bars, however, may impose a limit on the density of circuits, entail an extra process of removing the plating bars, and cause signal noise when there is residue left from the plating bars. In addition, the plating layer formed using the plating bars may not have a uniform thickness, and may be formed beyond the areas of the circuit pattern in which the pads are intended to be formed.

### SUMMARY

An aspect of the invention is to provide a printed circuit board and a method of manufacturing the printed circuit board that does not require the use of plating bars.

One aspect of the invention provides a method of manufacturing a printed circuit board that includes at least one pad and at least one circuit pattern. The method includes: forming a first plating resist corresponding to the circuit pattern on a surface of each of a first carrier and a second carrier; forming a second plating resist corresponding to the pad on each of the surfaces; forming the pad by performing plating over each of the surfaces; stripping the second plating resists; forming the circuit pattern by performing plating over each of the surfaces; pressing the first carrier and the second carrier with an insulation layer interposed between the first carrier and the second carrier such that the circuit patterns face each other; and removing the first carrier and the second carrier.

Here, the first plating resist and the second plating resist may be stripped by different stripper solutions, and the first plating resist and the second plating resist may include photosensitive material. In particular, the first plating resist can be a photosensitive insulator.

Between forming the circuit pattern and pressing the carriers, an operation of stripping the first plating resists may also be included. After removing the carriers, the method may further include forming a solder resist on the insulation layer such that the pad is exposed.

A conductive layer can be formed on the surfaces of the first and second carriers, and the method may further include removing the conductive layer, after removing the carriers. The method can also include operations of perforating a via hole in the insulation layer, and performing plating over the via hole, before the operation of removing the conductive layer. In such cases, the pad may be formed by performing electroplating.

The operation of forming the pad can include performing plating over the surfaces of the first carrier and the second carrier with different metals, and can include forming a first metal layer by performing plating over the surface of the first carrier with a first metal and forming a second metal layer by performing plating over a surface of the first metal layer with a second metal.

Another aspect of the invention provides a printed circuit board that includes: an insulation layer, a circuit pattern formed on a surface of the insulation layer, and a pad covering a portion of the circuit pattern, where the pad has a horizontal cross section substantially identical to a horizontal cross section of the portion of the circuit pattern.

Here, the circuit pattern and the pad can be buried in the insulation layer, and the circuit pattern can be formed on either surface of the insulation layer.

The pad can include a metal layer, which may cover a portion of the circuit pattern by a different thickness on either surface. The metal layer may include a different metal on either surface.

The printed circuit board may further include a solder resist that covers the circuit pattern, where an opening may be formed in the solder resist through which the pad may be exposed.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a printed circuit board according to an embodiment of the invention.

FIG. 2, FIG. 3, FIG. 4, FIG. 5, FIG. 6, FIG. 7, and FIG. 8 are cross-sectional views representing a method of forming a circuit pattern and a pad on a first carrier, according to an embodiment of the invention.

FIG. 9, FIG. 10, FIG. 11, FIG. 12, FIG. 13, FIG. 14, and FIG. 15 are cross-sectional views representing a method of forming a circuit pattern and pads on a second carrier, according to an embodiment of the invention.

FIG. 16, FIG. 17, FIG. 18, FIG. 19, FIG. 20, FIG. 21, and FIG. 22 are cross-sectional views representing a method of manufacturing a printed circuit board according to an embodiment of the invention.

FIG. 23 is a cross-sectional view of a printed circuit board according to another embodiment of the invention.

FIG. 24 is a perspective view of portion X in FIG. 23, according to another embodiment of the invention.

FIG. 25 is a perspective view of portion Y in FIG. 23, according to another embodiment of the invention.

### DETAILED DESCRIPTION

Certain embodiments of the invention will be described below in more detail with reference to the accompanying drawings. Those components that are the same or are in correspondence are rendered the same reference numeral regardless of the figure number, and redundant explanations are omitted.

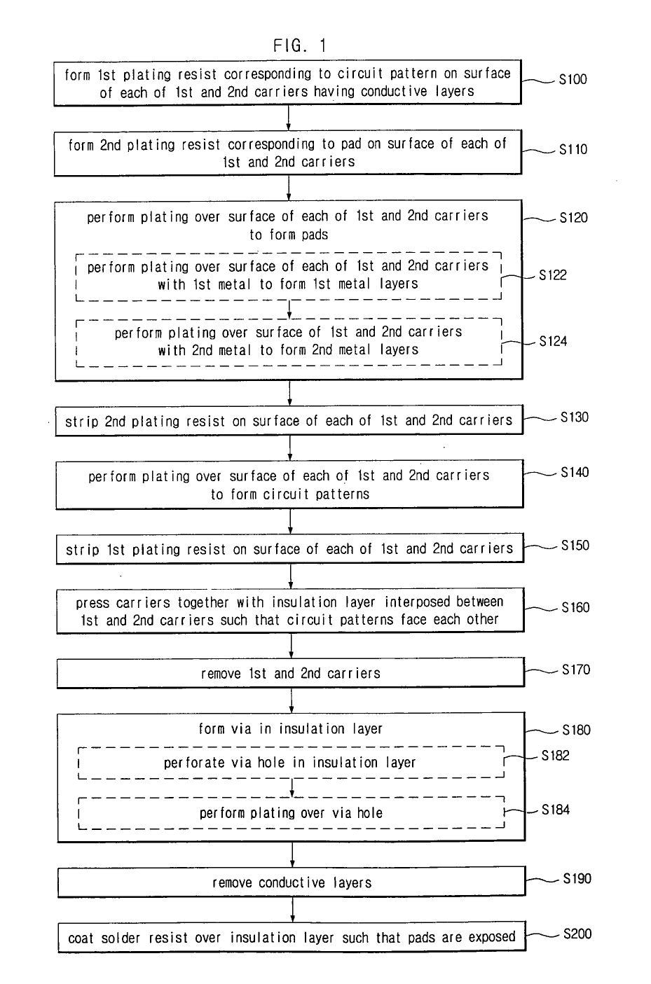

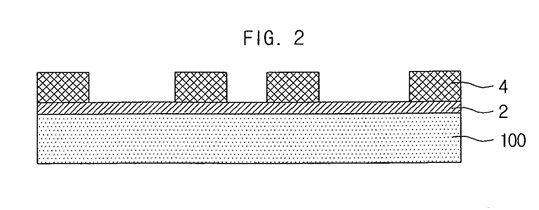

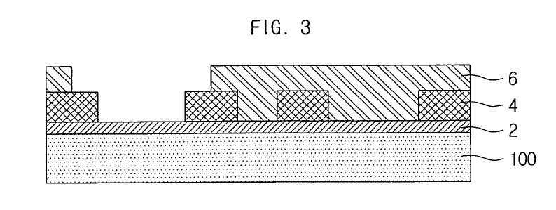

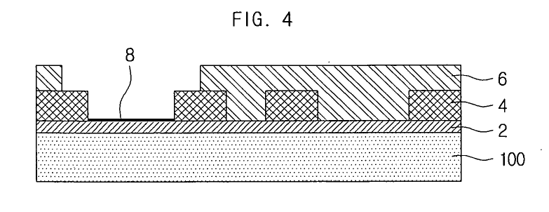

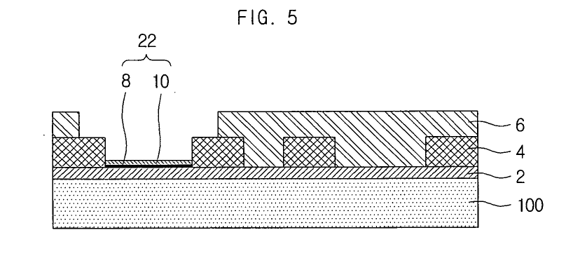

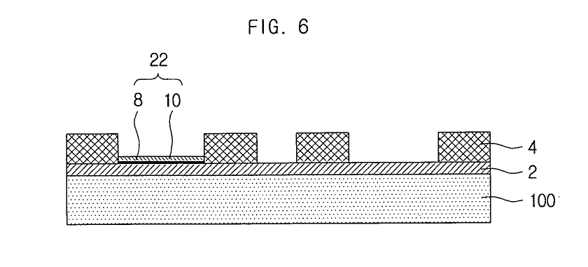

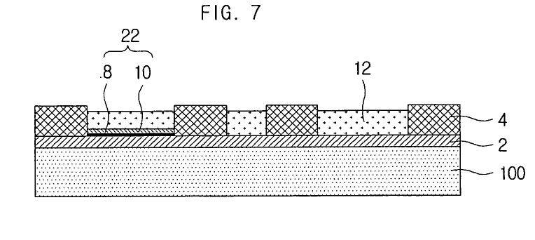

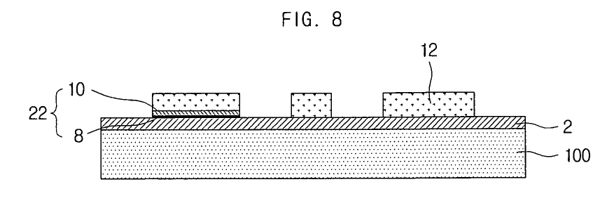

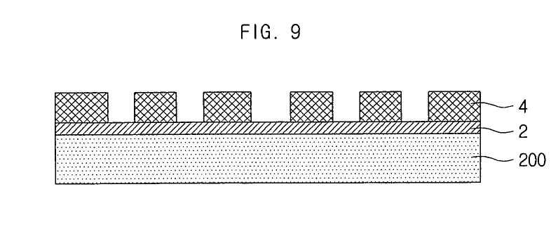

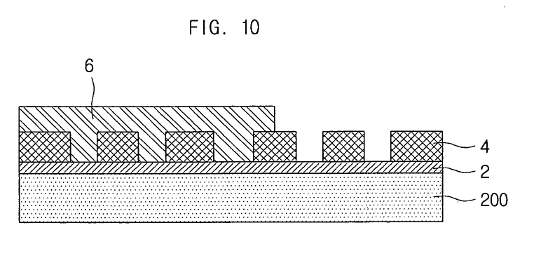

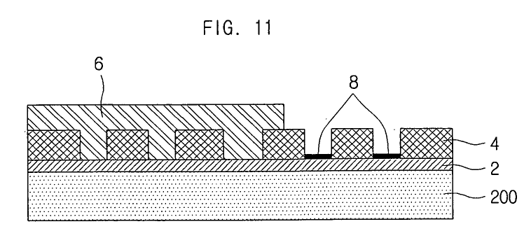

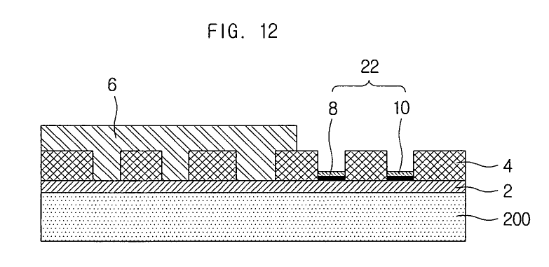

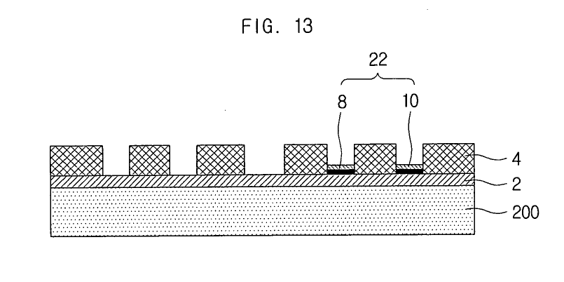

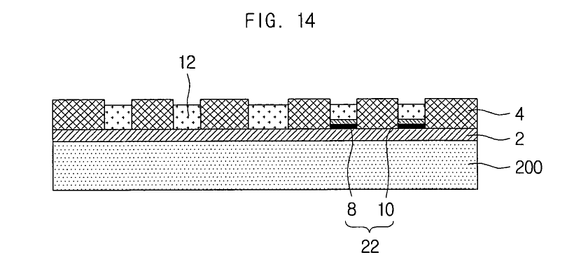

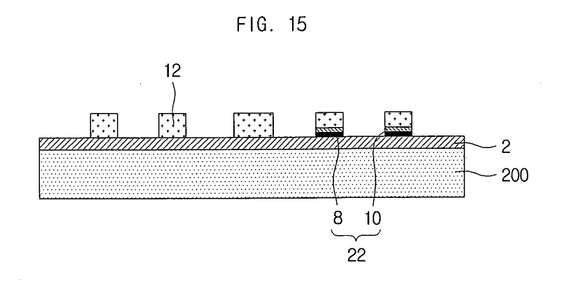

FIG. 1 is a flowchart illustrating a method of manufacturing a printed circuit board according to an embodiment of the invention, FIG. 2 through FIG. 8 are cross-sectional views representing a method of forming a circuit pattern and a pad on a first carrier, according to an embodiment of the invention, and FIG. 9 through FIG. 15 are cross-sectional views representing a method of forming a circuit pattern and pads on a second carrier, according to an embodiment of the invention. Also, FIG. 16 through FIG. 22 are cross-sectional views representing a method of manufacturing a printed circuit board according to an embodiment of the invention. In FIGS. 2 to 20 are illustrated a first carrier 100, a second carrier 200, conductive layers 2, first plating resists 4, second plating resists 6, first metal layers 8, second metal layers 10, circuit patterns 12, an insulation layer 14, a via hole 16, a via 18, solder resists 20, and pads 22.

With a method of manufacturing a printed circuit board according to the present embodiment, the printed circuit board can be manufactured by forming a circuit pattern 12 and pads 22 on each of a first and a second carrier 100, 200, and then stacking the layers together, so that pads 22 of different types or different thicknesses can be formed on either side without having to use plating bars.

First, a first plating resist 4 corresponding to a circuit pattern 12 may be formed over each of a first carrier 100 and a second carrier 200, which may have a conductive layer 2 formed on one surface (S100). A circuit pattern 12, etc., may be formed on the surface of the carrier 100, 200, which may serve as a support for sustaining the circuit pattern 12. The carrier 100, 200 can be made, for example, from copper (Cu).

As illustrated in FIG. 2 and FIG. 9, the conductive layer 2 may be formed on a surface of the carrier 100, 200. The conductive layer 2 can be made, for example, as a nickel (Ni) layer. The conductive layer 2 may be formed by performing plating over the carrier 100, 200. It is also possible to utilize the conductive layer 2 as a seed layer for a metal that may be plated over the carrier 100, 200.

On the surface of the carrier 100, 200 on which the conductive layer 2 is formed, a first plating resist 4 corresponding to the circuit pattern 12 may be formed. The first plating resist 4 may expose portions of the carrier 100, 200, in correspondence to the shape of the circuit pattern 12 that is to be formed on the carrier 100, 200. The first plating resist 4 may contain a photosensitive material, such as a liquid photoresist, for example. The liquid photoresist can be a material sensitive to ultraviolet (UV) rays. By a method of applying the liquid photoresist on the carrier and drying, an effect may be obtained similar to coating with dry film.

Onto the carrier 100, 200 coated with the liquid photoresist, an artwork film can be adhered, after which exposure and development processes may be performed to form the first plating resist 4 corresponding to the circuit pattern 12. Here, the “first plating resist 4 corresponding to the circuit pattern 12” may in certain cases refer to the first plating resist 4 that exposes those portions on the surface of the carrier 100, 200 where the circuit pattern 12 is to be formed.

Next, a second plating resist 6 corresponding to pads 22 may be formed over each of the first and second carriers 100, 200 (S110). A pad 22 may serve to provide electrical, physical coupling between a solder ball or a wire, etc., and the circuit pattern 12 formed on the printed circuit board, and may be made from one or more conductive material.

As illustrated in FIG. 3 and FIG. 10, the second plating resist 6 may be formed over the surface of the carrier 100, 200 on which the first plating resist 4 is formed. The second plating resist 6 may expose portions of the carrier 100, 200 that correspond to areas where the pads 22 are to be formed. The second plating resist 6 may include a photosensitive material that can be removed by a different stripping solution from the stripping solution used for the first plating resist 4. The second plating resist 6 can be, for example, a dry film.

Here, with regards the “different stripping solution,” even if the same type of chemical compound is used, if a solution is capable of selectively stripping one plating resist from among two different types, e.g. by utilizing a difference in concentration, then this solution can be considered a different stripping solution in the context of stripping the two types of plating resist. For example, while the liquid photoresist and the dry film described above can both be stripped by sodium hydroxide, two stripping solutions that both contain sodium hydroxide can be prepared with one of the solutions made to be capable of stripping just one of the two types of plating resist, by using different concentrations of sodium hydroxide. In such cases, the two solutions can be considered different stripping solutions in the context of stripping the two types of plating resist.

The first and second plating resists 4, 6 may serve to expose portions of the first carrier 100 corresponding to the circuit pattern 12 and the pads 22, respectively. While the first and second plating resists 4, 6 can be made of photosensitive materials as described above, other plating resist materials can be used that can be removed independently, examples of which may include metals that can be etched by different etchants.

Next, the pads 22 may be formed, by performing plating over the surface of each of the first and second carriers 100, 200 (S120). The forming of the pads 22 on the first and second carriers 100, 200 can be performed separately for each of the first and second carriers 100, 200. By proceeding with the operations for forming pads 22 separately, the pads 22 may be formed that are plated with different metals, or even if they are plated with the same metal, the pads 22 may be formed to different thicknesses.

In forming the pads 22 separately, the respective surfaces of the first and second carriers 100, 200 may be plated with a first metal, to form first metal layers 8 (S122). A first metal layer 8 may be a metal layer exposed at the outermost side of a completed pad 22, and can be made, for example, of gold (Au).

The gold plating may be performed by electroplating. The gold electroplating can be performed using nickel layers, i.e. the conductive layers 2 formed on the surfaces of the first and second carriers 100, 200, as seed layers. This may reduce the occurrence of the gold plating becoming detached, compared to those cases of employing electroless gold plating.

As illustrated in FIG. 4 and FIG. 11, the first metal layer 8 of the first carrier 100 may be made thinner, compared to the first metal layer 8 of the second carrier 200. For example, if the pads 22 of the first carrier 100 are used as solder ball pads, and the pads 22 of the second carrier 200 are used as wire bonding pads, the gold plating layer in the pads 22 of the first carrier 100 can be made thinner than the gold plating layer of the second carrier 200.

The thickness of the gold plating for a wire bonding pad can be, for example, 0.5 to 1.5 micrometers, while the thickness of the gold plating for a solder ball pad can be, for example, 0.03 to 0.25 micrometers. In the case of solder ball pads, the thinner the thickness of the gold plating, the higher may be the adhesion to solder balls. As such, solder ball pads and wire bonding pads can be treated differently, so that the reliability can be increased for the adhesion between solder ball pads and solder balls.

By proceeding with the plating for the pads 22 of the first and second carriers 100, 200 in separate processes, not only can the plating layers be given different thicknesses for either carrier, but also the plating may be performed with different metals. Furthermore, the plating processes can be performed differently for the first and second carriers 100, 200. As an example, plating may be performed with two types of metals for the first carrier 100, while plating may be performed with just one type of metal for the second carrier 200.

Next, the surfaces of the first and second carriers 100, 200 may be plated with a second metal, to form second metal layers 10 (S124). As illustrated in FIG. 5 and FIG. 12, the second metal layer 10 can be formed over the first metal layer 8. The second metal layer 10 can be made, for example, of nickel (Ni). The nickel plating can be performed by electroplating. By using electroplating for the plating of the nickel, difficulties in performing nickel plating over copper and problems of nickel corrosion, etc., may be avoided.

In plating the pads 22, the areas where the pads 22 are plated can be confined by a plating resist, to provide a uniform and well-defined plating layer in the areas where the pads 22 are formed. Since plating bars need not be used, the degree of freedom in designing circuits can be increased, and circuits of higher densities can be designed. Moreover, the occurrence of signal noise due to residue from plating bars may be prevented, so that the electrical properties of the printed circuit board may be improved.

Next, the second plating resists 6 on the first and second carriers 100, 200 may be removed (S130). As illustrated in FIG. 6 and FIG. 13, the first plating resists 4 can be left on the first and second carriers 100, 200, whereas the second plating resists 6 can be removed. As already described above, the first and second plating resists 6 may be such that can be removed by different stripping solutions. In cases where the second plating resists 6 are of dry film, a stripping solution containing sodium hydroxide (NaOH) may be used.

The stripping solution used here can be such that is capable of stripping the second plating resist 6 but incapable of stripping the first plating resist 4. If is possible to strip the first plating resist 4 and the second plating resist 6 with the same type of chemical compound, the concentration of the compound may be such that enables the stripping of the second plating resist 6 but does not enable the stripping of the first plating resist 4. When the second plating resists 6 are stripped, the plating resists 4 corresponding to the circuit patterns 12 may remain on the first and second carriers 100, 200.

Next, plating may be performed over the surfaces of the first and second carriers 100, 200 to form circuit pattern 12 (S140). As illustrated in FIG. 7 and FIG. 14, the first plating resists 4 may be formed to correspond to the circuit patterns 12. With the first plating resists 4 formed in place, the first and second carriers 100, 200 may be plated with a conductive material, e.g. copper (Cu), to form the circuit patterns 12. With the pads 22 already formed, the circuit patterns 12 may be plated on, so that the pads 22 and circuit patterns 12 may be electrically connected. As the nickel, i.e. the second metal layer 10 of the pads 22, may be used as a seed layer, the plating over the pad 22 portions may be facilitated.

Next, the first plating resists 4 on the first and second carriers 100, 200 may be removed (S150). As illustrated in FIG. 8 and FIG. 15, the first plating resists 4 may be removed to expose the circuit patterns 12 formed on the first and second carriers 100, 200. If the first plating resist 4 is formed from a liquid photoresist as described above, a stripping solution may be used that is capable of stripping the liquid photoresist. The stripping solution for the liquid photoresist can be such that is different from the stripping solution for the dry film. In certain examples, this can be sodium hydroxide of a different concentration from that for stripping the dry film. After removing the first plating resists 4, a black oxide treatment can be applied to the surface of the carrier 100, 200, as a pretreatment before stacking.

If the first plating resist 4 is made of a material such as a photosensitive insulator, that can serve both as a plating resist and as insulation, the operation of removing the first plating resist 4 may be omitted. In such cases, insulation layers 14 may be stacked on without removing the photosensitive insulators on the carriers, such that the removal of the first plating resists 4 is omitted.

Next, an insulation layer 14 may be placed between the first and second carriers 100, 200, and the carriers may be pressed together such that the circuit patterns 12 face each other (S160). As illustrated in FIG. 16, the first and second carriers 100, 200 can be aligned, with the circuit patterns 12 of the first and second carriers 100, 200 opposite to each other, and then the insulation layer 14 can be interposed in-between. The material used for the insulation layer 14 can be, for example, a thermosetting resin, etc. As illustrated in FIG. 17, the first and second carriers 100, 200 may be pressed together after placing the insulation layer 14 in-between. If a thermosetting resin is used for the insulation layer 14, the pressing may be accompanied by heating the thermosetting resin to a temperature that confers fluid characteristics to the thermosetting resin.

Next, the first and second carriers 100, 200 may be removed (S170). As illustrated in FIG. 18, the first and second carriers 100, 200 may be removed, leaving behind the insulation layer 14, in which buried circuit patterns 12 may be formed, and on the surfaces of which the conductive layers 2 may be formed. The removal of the carriers can be performed by any of various physical and chemical methods, according to the properties of the carriers. For example, if the first and second carriers 100, 200 are made of copper, the carriers can be removed using an etchant that is capable of etching copper.

Next, a via 18 may be formed in the insulation layer 14 (S180). Forming the via 18 may include, first, perforating a via hole 16 in the insulation layer 14 (S182). The operation of perforating the via hole 16 can be performed using a mechanical drill or a laser drill, etc. As illustrated in FIG. 19, the perforation may reach the circuit pattern 12 of the lower side, in order that the via 18 may be electrically connected with the lower circuit pattern 12.

To form the via 18, plating may then be performed over the via hole 16 (S184). As illustrated in FIG. 20, plating may be performed over the via hole 16 with a conductive material, such as copper, etc., to form a via 18. Here, the conductive layer 2 formed on the surfaces of the insulation layer 14, excluding the via hole 16, may serve to cover and protect the circuit patterns 12 buried in the insulation layer 14.

While the electrical connection between circuit patterns 12 on either side of the insulator can be provided by perforating via holes 16 and then performing plating to form vias 18, the electrical connection can also be provided by forming conductive paste bumps on the circuit pattern 12 of the first carrier 100 and then stacking such that the conductive paste bumps penetrate the insulation layer 14.

Next, the conductive layers 2 may be removed (S190). The removal of a conductive layer 2 may be achieved by any of various different methods according to the chemical properties of the conductive layer 2. If nickel is used for the conductive layer 2 as described above, the conductive layer 2 may be removed using an etchant that is capable of etching nickel. Here, the etchant used may be such that does not react with the circuit pattern 12, so that the circuit pattern 12 may not be damaged.

Next, solder resists 20 may be formed on the insulation layer 14 such that the pads 22 are exposed (S200). As illustrated in FIG. 22, solder resists corresponding to the pads 22 may be formed by a series of coating, exposure, development, and drying processes, such that the pads 22 formed on the insulation layer 14 are exposed to the exterior.

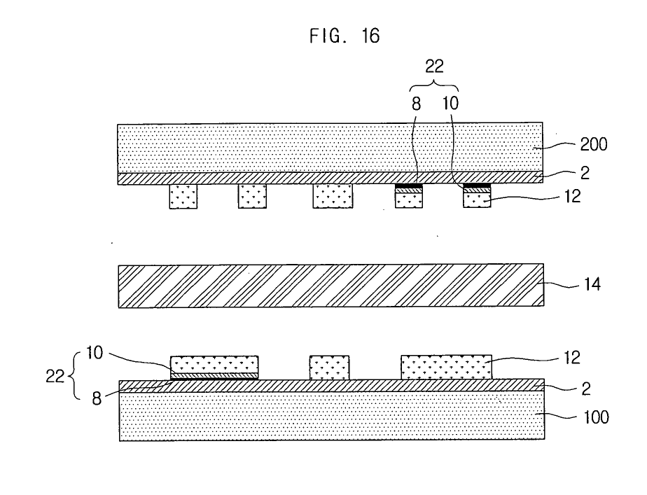

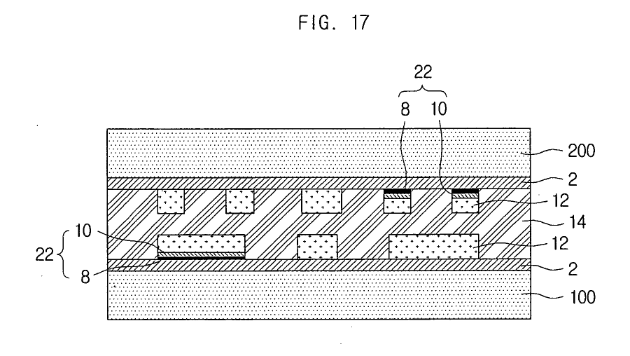

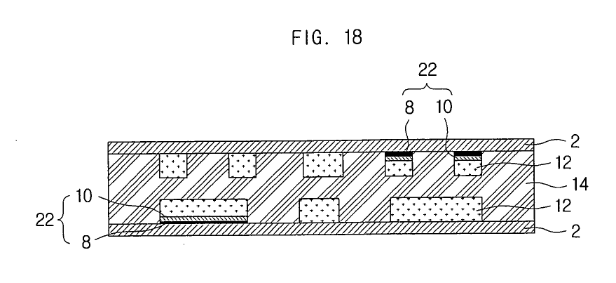

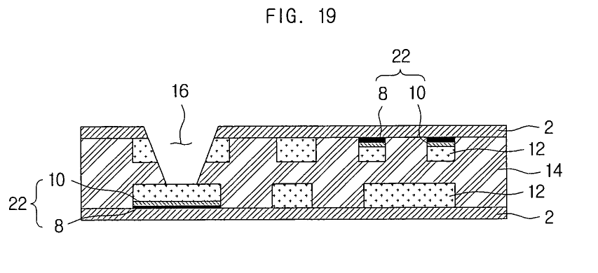

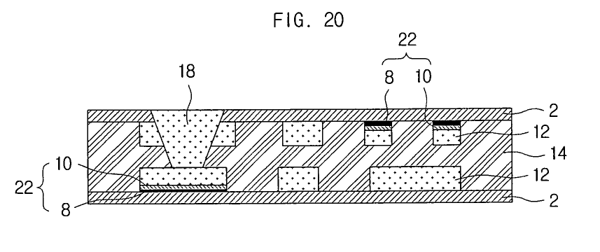

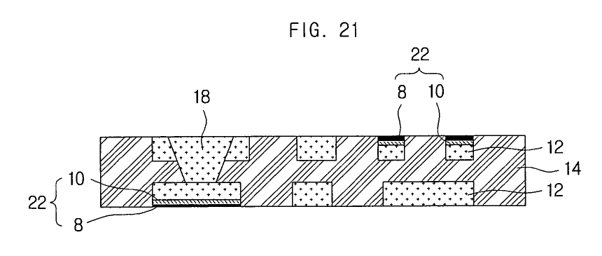

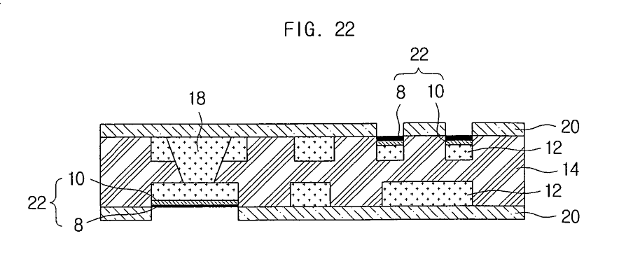

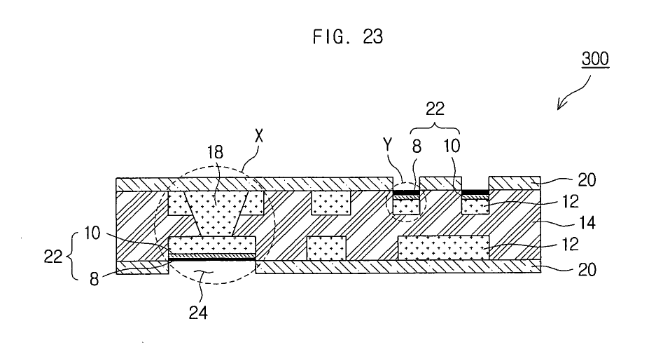

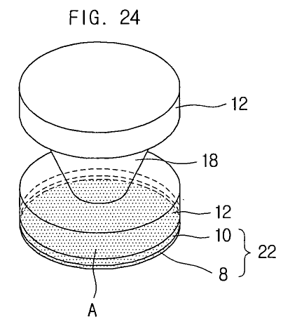

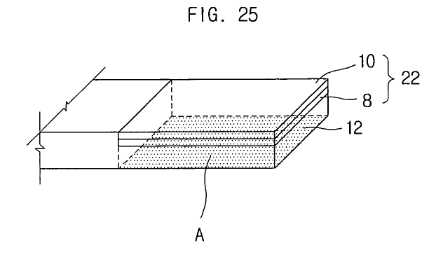

FIG. 23 is a cross-sectional view of a printed circuit board according to another embodiment of the invention, FIG. 24 is a perspective view of portion X in FIG. 23 according to another embodiment of the invention, and FIG. 25 is a perspective view of portion Y in FIG. 23 according to another embodiment of the invention.

The printed circuit board 300 according to another embodiment of the invention may include an insulation layer 14, as well as circuit patterns 12 and pads 22 covering portions of the circuit patterns 12, which are formed on the surfaces of the insulation layer 14. The horizontal cross sections of the pads 22 may be substantially the same as those of the portions of the circuit patterns 12. The pads 22 may be formed uniformly over the circuit patterns 12, to provide greater reliability in the physical and electrical coupling of components mounted on the printed circuit board 300.

A printed circuit board 300 based on this embodiment can be manufactured by a method of manufacturing a printed circuit board according to the previously described embodiment of the invention.

As illustrated in FIG. 23, the insulation layer 14 may be a thermosetting resin containing reinforcing material such as glass fibers, etc. The circuit patterns 12 may be formed buried on either side of the insulation layer 14. The circuit patterns 12 can be made of copper. The pads 22 may cover portions of the circuit patterns 12. The pads 22 can be metal layers, to provide electrical and physical connections to components mounted on the printed circuit board 300 or to another printed circuit board. The pads 22 may be, for example, wire bonding pads or solder ball pads. The printed circuit board may further include solder resists 20 which cover the circuit patterns 12, and in which openings 24 may be formed that expose the pads 22.

As illustrated in FIG. 24 and FIG. 25, the “portions of the circuit patterns 12” can refer to areas of the circuit patterns 12 covered by the pads 22. As illustrated in FIG. 24, a pad 22 may cover a portion of the circuit pattern 12, and may have substantially the same horizontal cross section (area denoted by A) as that of the portion of circuit pattern 12. To have the same horizontal cross section can mean that the portion of the circuit pattern 12, i.e. the area of the circuit pattern 12 where the pad 22 is to be formed, can have the pad 22 formed to the same shape and area (as denoted by A). Of course, the same may not necessarily mean absolute physical identicalness, but rather a sameness as allowable by manufacturing tolerances.

A pad 22 can cover a portion of the circuit pattern 12, and can have a horizontal cross section that is substantially the same as that of the portion of circuit pattern 12. The pads 22 may cover the portions of the circuit pattern 12 by a uniform thickness, so that a greater level of reliability may be obtained when the pads 22 are used to provide electrical and physical coupling to the exterior of the printed circuit board 300.

As illustrated in FIG. 25, when a pad 22 is formed, a portion of the circuit pattern 12 may become the area denoted by A that is covered by the pad 22. In this case also, the pad 22 and the portion of circuit pattern 12 may be formed to have substantially the same horizontal cross section.

As illustrated in FIG. 23, the pads 22 can be formed to include a metal layer, and can be formed with different thicknesses on either side of the printed circuit board 300. For example, the gold plating for wire bonding pads can have a thickness of 0.5 to 1.5 micrometers, while the gold plating for solder ball pads can have a thickness of 0.03 to 0.25 micrometers. For solder ball pads, the thinner the thickness of the gold plating, the higher may be the adhesion to solder balls. As such, solder ball pads and wire bonding pads can be treated differently, so that the reliability can be increased for the adhesion between solder ball pads and solder balls. Also, the plating layers on either side of the printed circuit board 300 may be formed including different metals. Of course, it is possible to form metal layers using both different metals and different thicknesses.

The printed circuit board 300 of this embodiment can be manufactured by a method of manufacturing a printed circuit board 300 according to the previously described embodiment of the invention. Thus, plating may be performed with plating resists corresponding to the circuit pattern 12 and the pads 22 formed over the carrier, to form the circuit pattern 12 and pads 22 separately. In this way, the pads 22 may be formed with substantially the same horizontal cross section as the portions of circuit patterns 12, as described in this embodiment.

As set forth above, with certain aspects of the invention, plating bars need not be used, so that the degree of freedom in designing circuits can be increased, and the circuits can be designed to higher densities. Furthermore, the occurrence of signal noise due to residue from plating bars can be prevented, so that the electrical properties of the printed circuit board can be improved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board having at least one pad and at least one circuit pattern, the method comprising:
forming a first plating resist corresponding to the circuit pattern on a surface of each of a first carrier and a second carrier;
forming a second plating resist corresponding to the pad on each of the surfaces;
forming the pad by performing plating over each of the surfaces;
stripping the second plating resists;
forming the circuit pattern by performing plating over each of the surfaces;
pressing the first carrier and the second carrier with an insulation layer interposed between the first carrier and the second carrier such that the circuit patterns face each other; and
removing the first carrier and the second carrier.

2. The method of claim 1, wherein the first plating resist and the second plating resist are stripped by different stripper solutions.

3. The method of claim 2, wherein the first plating resist and the second plating resist include a photosensitive material.

4. The method of claim 3, wherein the first plating resist is a photosensitive insulator.

5. The method of claim 3, further comprising, between forming the circuit pattern and pressing the carriers:
stripping the first plating resists.

6. The method of claim 1, further comprising, after removing the carriers:
forming a solder resist on the insulation layer such that the pad is exposed.

7. The method of claim 1, wherein a conductive layer is formed on the surface,
and the method further comprises, after removing the carriers:
removing the conductive layer.

8. The method of claim 7, further comprising, before removing the conductive layer:
perforating a via hole in the insulation layer; and
performing plating over the via hole.

9. The method of claim 7, wherein forming the pad comprises:
performing electroplating over the surface.

10. The method of claim 1, wherein forming the pad comprises:
performing plating over the surfaces of the first carrier and the second carrier with different metals.

11. The method of claim 1, wherein forming the pad comprises:
forming a first metal layer by performing plating over the surface of the first carrier with a first metal; and
forming a second metal layer by performing plating over a surface of the first metal layer with a second metal.

12. A printed circuit board comprising:
an insulation layer;
a circuit pattern formed on a surface of the insulation layer; and
a pad covering a portion of the circuit pattern,
wherein the pad has a horizontal cross section substantially identical to a horizontal cross section of the portion of the circuit pattern.

13. The printed circuit board of claim 12, wherein the circuit pattern and the pad are buried in the insulation layer.

14. The printed circuit board of claim 12, wherein the circuit pattern is formed on either surface of the insulation layer.

15. The printed circuit board of claim 14, wherein the pad comprises a metal layer.

16. The printed circuit board of claim 15, wherein the metal layer covers a portion of the circuit pattern by a different thickness on the either surface.

17. The printed circuit board of claim 15, wherein the metal layer comprises a different metal on the either surface.

18. The printed circuit board of claim 13, further comprising:
a solder resist having an opening formed therein and covering the circuit pattern, the opening configured to expose the pad.
